(19) United States
(12) Patent Application Publication
(10) Pub. No.: US 2009/0309604 A1
(43) Pub. Date: Dec. 17, 2009

(54) Electrostatic monitoring system

(76) Inventor: Yongming Zhang, San Diego, CA (US)

Correspondence Address: DIEDERIKS & WHITELAW, PLC, 13885 HEDGEWOOD DR., SUITE 317, WOODBRIDGE, VA, 22193, US

(21) Appl. No.: 11/919,403

(22) PCT Filed: May 5, 2006
(86) PCT No.: PCT/US06/17426

§ 371 Date: Oct. 26, 2007

Related U.S. Application Data
(60) Provisional application No. 60/678,196, filed on May 6, 2005.

(51) Int. Cl. G01R 29/12

(52) U.S. Cl. 324/457

(57) ABSTRACT

An electrostatic monitoring system for detecting a risk of electrostatic discharge is used to detect conditions under which electrostatic discharge is likely, at distances sufficient to provide the time needed to take corrective action and mitigate any harmful effects. The system monitors electrostatic discharge conditions in the order of a few meters away, and preferably determines the direction of maximum hazard. By the invention, personnel can be screened upon entering a vulnerable area, sensitive equipment can be protected by placing sensors on the equipment to detect the risk of electrostatic discharge due to the local static potential and to preemptively turn off the equipment, and wearable sensors can be installed in clothing of personnel working in environments with high electrostatic hazard to protect both personnel and equipment.

### CROSS-REFERENCE TO RELATED APPLICATIONS

The present application claims the benefit of U.S. Provisional Patent Application Ser. No. 60/678,196 entitled “Large Standoff, Direction Finding, Wearable Electrostatic Discharge Detection System” filed on May 6, 2005.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of contract Nos. NNK04OA22C and NNK05OA05C, awarded by NASA under two SBIR programs, Phase I and Phase II.

### BACKGROUND OF THE INVENTION

The present invention generally pertains to the art of measuring the buildup and discharge of electrostatic charges. More particularly, the invention relates to using free-space electric field sensors to detect a buildup of electrostatic charge in various types of situations.

Spontaneous electrostatic discharge has been a problem in numerous different fields for many years. Essentially a human body will tend to generate a static electric charge when parts of the body come in frictional contact with other surfaces. Triboelectric charging, as the phenomenon is known, results in a gradual buildup of electric charge that is notoriously hard to detect in a timely manner.

For example, the buildup of electrostatic charge can be particularly troublesome in the field of flammable fluid distribution. The reduction of sources of electrostatic potential is important in order to reduce the chance of explosion or fire. The amount of electrostatic charge needed to ignite vaporized gasoline is extremely small. To overcome this problem, gasoline fueling systems, such as filling trucks and filling pumps, are typically grounded. If such a system detects an improper ground then the gasoline will not flow. Furthermore, when motorists refuel automobiles they are admonished to not use cell phones or other electronic devices that could potentially cause an electric discharge.

Electrostatic discharge is also a problem in the production of electronic devices such as computer memory, semiconductor wafers or a personal computer motherboard. Indeed a small discharge, too small for a person to detect, may still be large enough to damage an electronic device. One way to address the electrostatic discharge problem is to use conducting floor tiles, humidity control, and other means of inducing a slow discharge of the offending high potential source. These alternatives are widely used, but are not 100% successful in addressing the problem.

Currently, when a computer is being manufactured or repaired technicians will routinely ground themselves before working on various electronic components of the computer. Simply touching a ground on a power supply or using special clothing will help to avoid a sudden discharge of electrostatic potential that will damage the various components of the computer, such as random access memory which can be particularly sensitive to such currents. Grounding straps, which are typically worn on a person's wrist, are also common in such manufacturing environments. However, simply grounding equipment and personnel has not proven sufficient. People sometimes forget to wear grounding straps or will enter a sensitive area, such as an area where semiconductor wafers are being made, and produce destructive electrostatic discharge events before putting on a grounding strap.

Any situation in which an electrostatic charge can build up and discharge in the vicinity of flammable liquid or vapor is a hazardous situation. Any type of facility with machinery whose motion can build up a charge in the presence of any flammable substance can benefit from electrostatic monitoring. Some industries with a history of electrostatic discharge related accidents include: Gasoline Vending, Transporting and Storage; Oil Refining; Shipping; Paper Processing; Chemical Manufacturing; and Fiberglass-related manufacturing (boats).

The combination of shrinking product geometries and increasing sensitivity has left many products and manufacturing processes vulnerable to even modest levels of electrostatic charge. Product and process contamination through electrostatic attraction has been and remains a critical issue in numerous industries. Pulse EMI (E-field and H-field components) generated by electrostatic discharges has probably caused more mysterious problems for more processes and products than any other single source. High electric fields lead to electrostatic discharge that can injure personnel or damage or destroy sensitive apparatus such as semiconductor wafers and chips during the fabrication stages. Effective control requires monitoring and intervention prior to charge imbalances reaching critical thresholds. Industries for which this is applicable include, among others: Semiconductor Manufacturing; Flat Panel Display Manufacturing; Disk Drive Manufacturing; Medical Manufacturing; Pharmaceutical Processes; Military Contractors; MEMS Technology and Nanotechnology.

Based on the above, certain solutions have been proposed. For instance, some manufacturers have produced handheld devices that can detect a 1000V source at a distance of 1 cm. However such devices are woefully inadequate in giving enough warning to workers in a production line to stop an electromagnetic discharge or in screening personnel as they enter sensitive areas.

U.S. Pat. No. 6,150,945 discloses a wearable device for measuring static charge buildup on a user. People working around sensitive electronic equipment use the device. However, the device detects static buildup on the wearer and does not identify a static potential difference to other objects.

U.S. Pat. No. 5,218,306 is a wearable static charge warning device that detects charge flow to or from a needle point worn on a wrist or elsewhere on a body. The charge flow can be indicative of a possible electrostatic discharge hazard. The warning device does not detect hazardous voltages, but rather it only detects charge flow.

U.S. Pat. No. 5,461,369 relates to a wearable device for detecting electrostatic discharge events. The device does not warn of dangerous potentials prior to an actual discharge.

U.S. Pat. No. 4,007,418 describes an electrostatic safety monitor that can be carried or worn. This device generates a signal when detecting the transfer of energy from a human body to its surrounding. While such detection is useful, it does not provide advanced warning of electrostatic discharge, but instead relies on the discharge itself to generate the signal. In this respect it fails to supply advanced warning of electrostatic hazards and only provides a warning after discharge has occurred and damage possibly done. Another consequence of detecting energy transfer is that essentially no standoff detection is provided.

As can be seen from the above discussion, there exists a need in the art for a compact electric potential sensor for monitoring ambient electric fields in different modalities. The sensor should be able to detect conditions under which electrostatic discharge is likely, at distances sufficient to provide the time needed to take corrective action and mitigate any harmful effects.

### SUMMARY OF THE INVENTION

The present invention is directed to an electrostatic monitoring system for detecting a risk of electrostatic discharge and for monitoring ambient electric fields in different modalities. The system is compact and extremely sensitive compared to existing systems. The system is used to detect conditions under which electrostatic discharge is likely, at distances sufficient to allow coverage of a section of a process area, and with enough precision to provide warning in time to take corrective action and mitigate any harmful effects. The system monitors electrostatic discharge conditions a few meters away, and also provides a means to determine the direction of maximum hazard.

The system may be used for at least the following three modes of operation: personnel are screened upon entering a vulnerable area by having sensors placed on doorways to screen them for high electrostatic charge on their bodies when they enter a sensitive facility; equipment is protected by placing sensors on sensitive equipment to detect the risk of electrostatic discharge due to the local static potential in order to turn off the equipment or otherwise warn a worker away from the equipment; and wearable sensors are installed in clothing of personnel working in environments with high electrostatic hazard to protect both personnel and equipment.

More specifically, the invention concerns an electrostatic monitoring system for detecting a risk of electrostatic discharge by measuring a static electric field potential of an electric field produced by a source and alerting appropriate personnel when the electrical field potential exceeds a preset limit. The system includes a sensor having an electrode, located near, but not in direct contact with, the source, for producing a sensed signal voltage based on the static electric field potential. A pre-amplifier has an input electrically connected to the electrode by an electrical path. The pre-amplifier produces an amplified voltage signal based on the sensed signal. A controller receives the amplified voltage signal and determines if the amplified voltage signal is above a predetermined threshold. If the amplified voltage signal is above the threshold, then a user is notified of the risk of electrostatic discharge.

In one preferred embodiment, the system includes a ground electrode and a resistor having an input shunt resistance of 1 Teraohm that is located between the electrical path and the ground electrode. The sensor further includes processing circuitry that preferably includes a capacitor located between the electrical path and ground. Such a capacitor adds a shunt capacitance of approximately 1 picofarad. For even better results, the sensor further includes a feedback circuit having a feedback amplifier, such as an op-amp with two inputs and an output, with the output of the pre-amplifier being connected to one input of the feedback amplifier and the output of the feedback amplifier being connected to the input of the pre-amplifier. A resistor having a resistance value of at least 10 Mega-ohms is provided in the feedback path. Optionally, a second sensor may be added. The second sensor also includes a second electrode located near, but not in direct contact with, the source for producing a second sensed signal voltage based on the static electric field potential, a second pre-amplifier having an input electrically connected to the second electrode by an electrical path and an output. The second pre-amplifier produces a second amplified voltage signal at the output based on the sensed signal, wherein the controller receives the second amplified voltage signal. The first and second sensors are mounted in an array and the controller is adapted to use the first amplified voltage signal and the second amplified voltage signal to determine a direction to the source. Optionally additional sensors may be added for enhanced accuracy and/or verification purposes.

In one preferred embodiment, the system includes the first and second sensors mounted on a doorway, with the system being adapted to detect the electrostatic potential of people passing through the doorway. Since doorways can cause field distortion, the system preferably uses an AC source used to compensate for the distortion.

In yet another preferred embodiment the first and second sensors are mounted close to a machine that is sensitive to electrostatic discharge. The system employs a mounting fixture for supporting the sensors. In this configuration, the first sensor is mounted at least 2 cm away from the machine, while the second sensor is mounted at least 2 cm away from the first sensor and at least 4 cm away from the machine. The machine is preferably a gasoline pump or a semiconductor wafer production line.

In yet another preferred embodiment, the system is wearable on a human body and a ground electrode is adapted to be in electrical contact with the body. For example the sensor may be mounted on a hat such that, when the hat is worn, the sensor will be positioned away from the body. Preferably the hat has a visor, with the sensor being mounted on the visor and the ground electrode being mounted on a brim of the hat near the wearer's forehead. The brim is made of conductive fabric so that the ground electrode can make electrical contact with the body through the fabric. Alternatively the sensor can be mounted on a sleeve of a garment, such as a chemical safety suit, or on a pair of safety glasses. In a still further embodiment, the system may be mounted on a badge.

In use the system is employed to detect a risk of electrostatic discharge by first measuring a static electric field potential of an electric field produced by a distant source and then producing a signal representative of the field potential. Distortion is then removed from the signal and an alert is produced when the electric field potential exceeds a preset limit so that the electric field potential can be reduced in a harmless manner before an electrostatic discharge occurs. Also the direction to the source of the electric field may be determined.

Additional objects, features and advantages of the present invention will become more readily apparent from the following detailed description of a preferred embodiment when taken in conjunction with the drawings wherein like reference numerals refer to corresponding parts in the several views.

### BRIEF DESCRIPTION OF THE DRAWINGS

FIG. 1 shows a perspective view of an electrostatic monitoring system with sensors mounted on a door to a vulnerable area in accordance with a first preferred embodiment of the invention;

FIG. 2 is a circuit diagram of the electrostatic monitoring system of FIG. 1 including a feedback loop;

FIG. 3 is a circuit diagram of the electrostatic monitoring system of FIG. 1 including an analog switch;

FIG. 4 shows perspective view of the electrostatic monitoring system with sensors mounted on a handle of a gasoline pump according to a second preferred embodiment of the invention;

FIG. 5 shows a schematic side view of the electrostatic monitoring system with a sensor mounted in a semiconductor wafer production line according to a third embodiment of the invention;

FIG. 6 shows side view of an electrostatic monitoring system with sensors mounted on equipment according to a fourth preferred embodiment of the invention and sensors mounted on clothing according to a fifth preferred embodiment of the invention;

FIG. 7 shows a model used to simulate the electrostatic monitoring system of FIG. 6 when the sensors are mounted in different positions on clothing; and

FIG. 8 is graph developed with the model shown in FIG. 7, showing an electrical potential distribution from a 1 kV voltage source with and without a human body present.

### DETAILED DESCRIPTION OF THE PREFERRED EMBODIMENTS

In general, an electrostatic discharge occurs when static electricity has accumulated a charge on a surface to a point where an electric potential of the charge is sufficient to have the charge jump across a gap from the surface to an object with a lower electric potential, sometimes called a ground. As mentioned above, a human body can generate such a charge when rubbing against a surface of high friction. Typically, people experience so called “triboelectric charging” when they rub their feet on a carpet. They then experience an electrostatic discharge or spark when they touch a doorknob. When such a discharge passes through a sensitive electronic component, the component may be damaged. When the discharge passes through vaporized flammable gas, ignition results, along with a number of particularly unpleasant results.

When a built-up static charge cannot find an easy path to ground, the charge creates an electric field that emanates away from the charge surface. As the charge gets larger, so does the field's strength. It is this electric field that can be sensed to determine when the built-up static electric charge is getting dangerously large and therefore a discharge may be presumed to be imminent. The present invention provides an electric field sensing device that senses, from a distance, the level of static charge and provides a warning before the field strength reaches a potentially dangerous level.

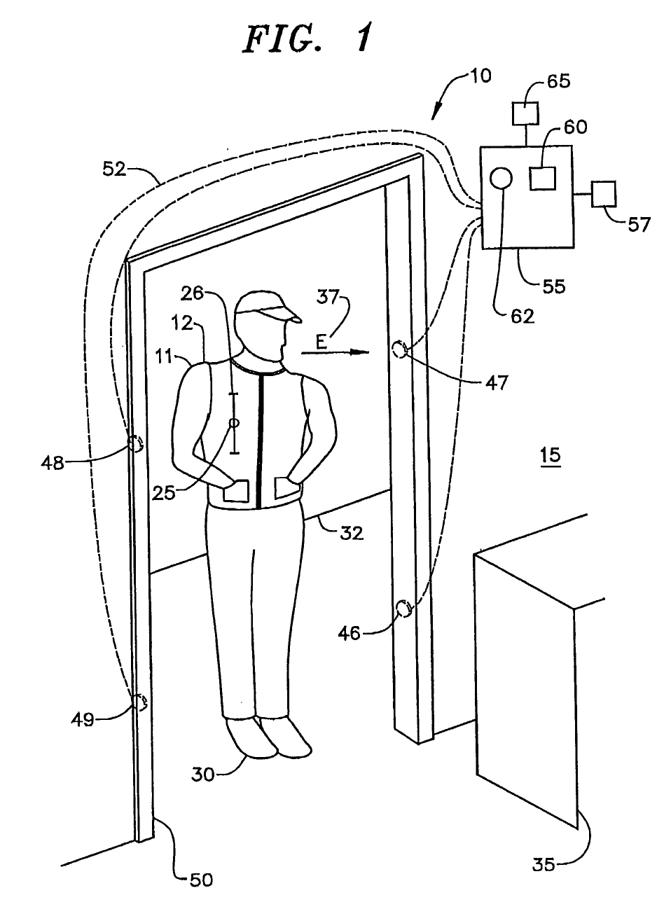

As will become fully evident below, the present invention can take various forms, depending on the particular application. With initial reference to FIG. 1, an electrostatic monitoring system constructed in accordance with one embodiment of the invention is generally indicated at 10. Monitoring system 10 is designed so that an object 11, such as a person 12, is screened upon entering a vulnerable area 15. In this case, person 12 includes a source 25 having an electrostatic voltage charge potential 26. For instance, person 12 may have rubbed his feet 30 on a carpet 32 or may have created electrostatic voltage charge potential 26 some other way. Regardless, how charge potential 26 is generated is not important. Instead, detecting electrostatic voltage charge potential 26 on person 12 before person 12 enters vulnerable area 15 with sensitive equipment 35 is important.

As depicted in FIG. 1, source 25 creates electrostatic voltage charge potential 26 which, in turn, creates an electric field 37 that emanates from person 12. In this case, electric field 37 is shown schematically as a unidirectional vector E, but it should be understood that field 37 actually emanates in all directions. In accordance with the embodiment shown, monitoring system 10 includes sensors 46-49 placed on a doorway or gateway 50. Each of sensors 46-49 is about the size of a coin, such as a penny or dime, and is preferably connected via respective wiring 52 to a central control unit 55. Each sensor 46-49 has its own internal circuitry, as detailed further below, that can be tailored to a particular mounting arrangement. In operation, each sensor 46-49 sends a signal to control unit 55 which may then provide warnings directly to person 12 or other personnel, such as through a visual and/or audible alarm 57, that there is a danger of an electrostatic discharge event. To rectify the situation, precautionary measures, such as having person 12 touch a grounding unit (not shown), can be performed, thereby making it safe for person 12 to enter vulnerable area 15. In a preferred embodiment, control unit 55 is provided with a memory unit 60 to record an event time, along with the corresponding level of static charge detected, for later data downloading and analysis.

Sensitive equipment 35 provided in vulnerable area 15 may take many forms. For instance, sensors 46-49 on doorway 50 could monitor electrostatic voltage charge potential 26 of person 12 entering an electrostatic discharge vulnerable area 15 of a wafer process room, a gas handling facility or a NASA vehicle assembly facility. While one or more sensors 46-49 in doorway 50 may be used to detect electrostatic voltage charge potential 26 of object 11 passing through doorway 50, preferably four sensors 46-49 are used to achieve a high level of detection. At this point, it should be realized that various objects could be monitored and the particular monitoring arrangement would be accordingly designed. For instance, a conveyor arrangement (not shown) could be utilized in combination with sensors 46-49 to scan objects entering vulnerable area 15. In any case, in the embodiment shown, control unit 55 uses an algorithm preferably implemented on a microprocessor to detect electrostatic voltage charge potential 26 of person 12 walking through doorway 50. The potential varies as 1/r² (where r is the distance of the person 12 from the particular sensor 46-49). Based on this measurement result, the electrostatic voltage charge potential 26 represented by the variable Va as detected by one or more of sensors 46-49 is represented by:

$$Va = a * \frac{V}{{r}^{2}} \qquad ( 1 )$$

where r is a distance between person 12 and a sensor, for example, sensor 46, a is a calibration coefficient, and V is the potential of person 12. In the case of doorway 50, considering top two sensors 48 and 47, the potential detected by sensors 47 and 48 when person 12 is at a distance r from sensor 48 is given by the equations (1) and (2) respectively,

$$Vb = a * \frac{V}{{( L - b - r )}^{2}} \qquad ( 2 )$$

where L is the width of doorway 50 and b is the width of person 12. Solving equations (1) and (2), we can calculate the absolute potential V on person 12 for a known value of L, b and a. Considering absolute values of Va and Vb and solving equations (1) and (2), we have

$$V = \frac{{( L - b )}^{2} * Va * Vb}{a ( Va + Vb + 2 \sqrt{Va} \sqrt{Vb} )} \qquad ( 3 )$$

The potential V on person 12 is then calculated using equation (3). By knowing the potential of person 12, system 10 is able to provide a warning signal if the potential is above a threshold, which can be set for different applications. Again, if the detected electrostatic voltage charge potential 26 is greater than a predetermined limit, alarm 57 is activated or some other measure is taken to prevent person 12 from entering vulnerable area 15 for safety reasons. It should be recognized that, if doorway 50 is made of metal, a distortion to electric or E-field 37 will be created near doorway 50 where sensors 46-49 are mounted. However, this distortion is effectively calibrated out in accordance with the invention by providing an AC source 65, which is connected to control unit 55, in doorway 50.

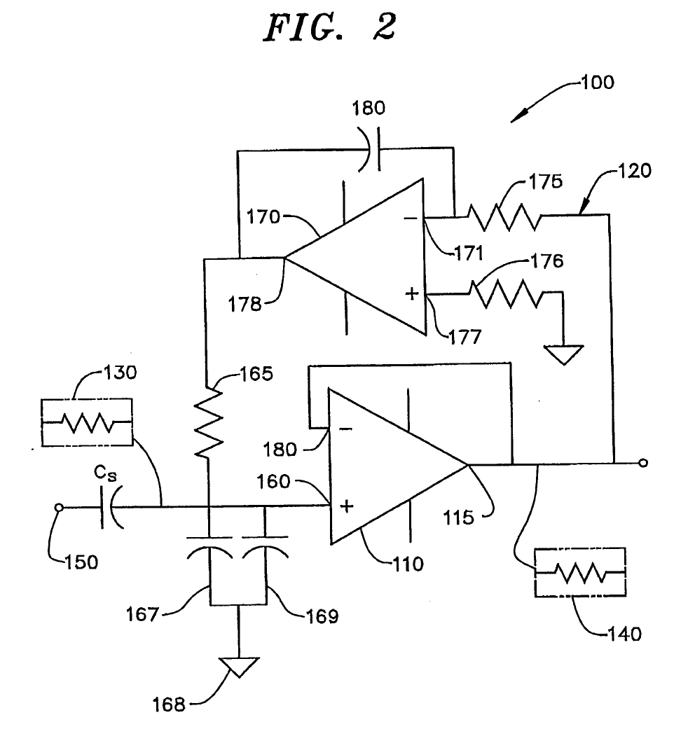

A circuit 100 preferably employed in connection with each of sensors 46-49 of the present invention is shown in FIG. 2. In general circuit 100 includes a preamplifier 110 having an output 115 connected to a feedback path 120. Circuit 100 functions to measure a voltage signal 130 representative of the size of electrical field 37 that is created by the electrostatic voltage charge potential 26 on measured object 11, amplifies voltage signal 130 and sends an amplified signal 140 to control unit 55. More specifically, circuit 100 includes a capacitive sensing electrode 150 that senses voltage signal 130. Electrode 150 has an associated capacitance Cs, such as about 0.043 Pico farads. Voltage signal 130 travels from electrode 150 to a non-inverting input 160 of preamplifier 110. An input shunt resistor 165, preferably in the order of 1 Terra Ohm, is provided at amplifier input 160. Additionally, a shunt capacitance 167 to ground 168, preferably 1 or 5 pf, is added at input 160 to preamplifier 110. In general, a 5 pf shunt capacitance is considered preferable in that it provides a flatter frequency response and thus less signal distortion.

Preamplifier 110 is preferably an operational amplifier and is shown to have an input capacitance 169, such as in the order of 1 pf. Various standard operational amplifiers of a correct size could be used, such as ultra low bias current operational amplifier model OPA 129 produced by Burr-Brown products of Texas Instruments. As shown, output 115 of preamplifier 110 is also connected back to inverting input 180 of preamplifier 110. Additionally output 115 from preamplifier 110 is sent to feedback path 120.

Feedback path 120 includes a feedback amplifier 170 that is also an operational amplifier. Feedback path 120 is used to reduce a DC offset at input 160 of preamplifier 110. In particular, output 115 from pre-amplifier 110 is sent to an inverting input 171 of feedback amplifier 170 through a resistor 175. In the preferred embodiment, resistor 175 has a value of 10 M ohm. The placement of resistor 175 reduces both overshoot and an idle period. Another resistor 176, also in the order of 10 M ohm, is provided between a non-inverting input 177 of feedback amplifier 170 and ground 168. An output 178 of feedback amplifier 170 travels through shunt resistor 165 and then returns to non-inverting input 160 of pre-amplifier 110. Output 178 from feedback amplifier 170 is also connected back to inverting input 171 of feedback amplifier 170. Once again, while most standard operational amplifiers of a correct size could be used, a preferred amplifier is micro-power single supply operational amplifier model OPA2244 produced by Burr-Brown products of Texas Instruments.

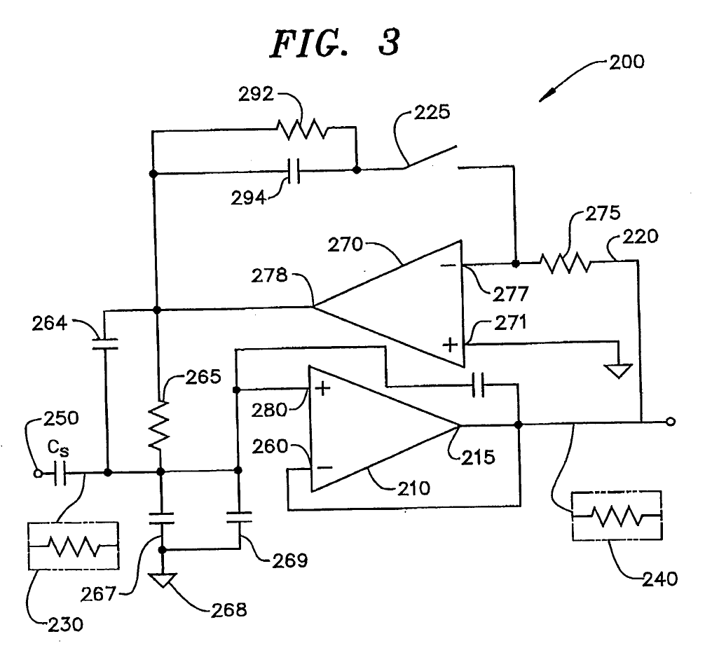

Referring now to FIG. 3, there is shown a schematic of another circuit 200 which can be employed with one or more of sensors 46-49, wherein circuit 200 includes a preamplifier 210 having an output 215 connected to a feedback path 220 and an additional analog switch 225 added to reduce recovery time of sensors 46-49. Circuit 200 measures a voltage signal 230 representative of the size of electric field 37 that is created by electrostatic voltage charge potential 26 of measured object 11, amplifies voltage signal 230 and sends an amplified signal 240 to control unit 55. More specifically, circuit 200 includes a sensing electrode 250 that senses voltage signal 230. Electrode 250 has an associated capacitance Cs, preferably about 0.043 Pico farads. Voltage signal 230 travels from electrode 250 to preamplifier 210. An input shunt capacitor 264 and an input shunt resistor 265, preferably in the order of 1 Terra Ohm, is provided in parallel between at amplifier input 280. Additionally, a shunt capacitor 267, having a capacitance of preferably 1 pf or 5 pf, is added at input 280 to preamplifier 210. For the reasons set forth above in connection with the embodiment of FIG. 2, a 5 pf shunt capacitance is considered preferable.

Similarly, preamplifier 210 is preferably an operational amplifier with a 1 pf input capacitance 269, such as ultra low bias current operational amplifier model OPA 129 produced by Burr-Brown products from Texas Instruments. In any case, amplifier 210 sends an output voltage signal 240 through wires 52 to control unit 55. Output 285 of preamplifier 210 is connected back to inverting input 260 of preamplifier 210. Additionally output 215 from preamplifier 210 is sent to feedback path 220.

In a manner corresponding to the previously described embodiment, feedback path 220 includes a feedback amplifier 270 that is also an operational amplifier. In particular, output 215 from preamplifier 210 is sent to an inverting input 277 of feedback amplifier 270 through a resistor 275. In a preferred embodiment, resistor 275 has a value of 10 M ohm. A non-inverting input 271 of feedback amplifier 270 is connected to ground 268. Output 278 of feedback amplifier 270 travels through a shunt resistor 265, preferably having a value of 1 Terra ohm, and then returns to non-inverting input 280 of preamplifier 210. Once again, while most standard operational amplifiers of a correct size could be used, a preferred amplifier is a micro-power single supply operational amplifier model OPA2244 produced by Burr-Brown products from Texas Instruments.

Of particular distinction in connection with the FIG. 3 embodiment is the presence of analog switch 225 between output 215 of preamplifier amplifier 210 and non-inverting input 280 of preamplifier 210. As shown, analog switch 225 is in series with parallel arranged resistor 292 and capacitor 294. Capacitor 294 has a preferred value of 10 microfarads, while resistor 292 has a preferred value of 50 mega ohms or larger. While most standard analog switches could be employed, a preferred switch is a quad analog switch produced by Maxim products from Dallas Semiconductor. Switch 255 is controlled by a digital output from module 55. When output voltage signal 240 is larger than a specified high threshold level, module 55 opens switch 255 until output voltage signal 240 falls below a set low threshold level.

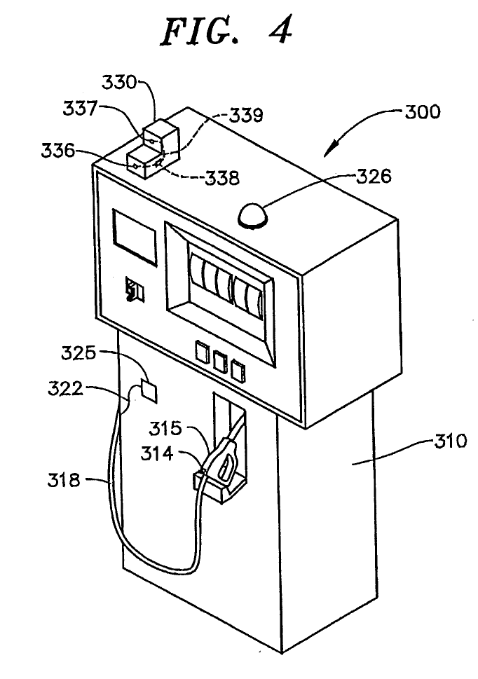

As indicated above, the electrostatic monitoring system of the invention can take various forms and be used in a wide range of applications. Turning now to FIG. 4, there is shown an electrostatic monitoring system 300 constructed in accordance with another embodiment of the invention. As shown, monitoring system 300 is mounted on a piece of equipment that is sensitive to electrostatic discharge. More particularly monitoring system 300 is shown mounted on a gasoline pump 310. System 300 may be mounted in numerous different places, but preferably includes a sensor 314 mounted on a dispensing handle 315. More specifically, a single sensor 314 or multiple sensors may be mounted on handle 315 having an associated hose 318, while a wire 322 travels along dispensing hose 318 and to a controller 325 and an alarm 326.

Alternatively, a mounting fixture 330 may hold one or more capacitive sensors 336 and 337. Mounting fixture 330 preferably keeps one sensor 336 at least 2 cm away from pump 310 and keeps a second sensor 337 at least 2 cm away from first sensor 336 and 4 cm away from pump 310. Sensors 336 and 337 are connected to a controller 338 by wiring 339. In either embodiment, if a person approaches pump 310, a visual and/or audible warning will be given by alarm 326 if the person/object has accumulated a dangerously large static electric charge. In one preferred form of the invention, controller 325 of system 300 actually disables pump 310 until the high static potential has been safely discharged.

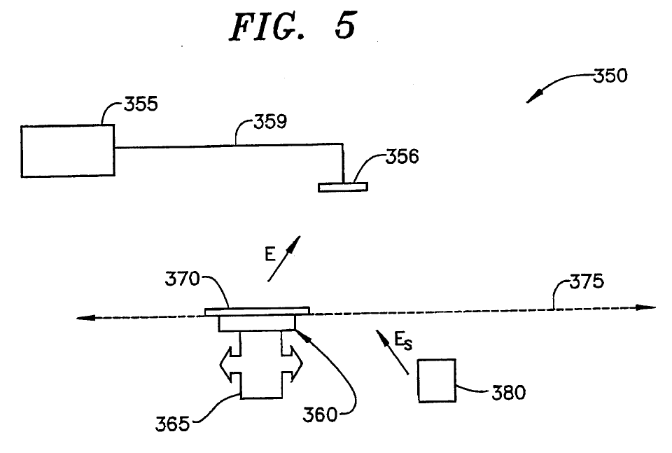

Turning now to FIG. 5, there is shown an electrostatic monitoring system 350 constructed in accordance with another preferred embodiment of the invention. As shown, monitoring system 350 includes a control module 355 analogous to control module 55 discussed above. In addition, a sensor 356 is connected to control module 355 via a communication line 359. In this embodiment, monitoring system 350 is shown in a semi-conductor wafer production line 360. Production line 360 includes a robotic arm assembly 365 which carries a semiconductor wafer 370 along a robotic process pathway 375. Sensor 356 is mounted so as to face semiconductor wafer 370 and measure an electric field E emanating therefrom. Sensor 356 is particularly sensitive so as to allow for remote measurement and monitoring of electrostatic charges on semiconductor wafer 370. In addition, the sensitivity of sensor 356 allows for discrimination between electrostatic charges on wafer 370 verses electrostatic charges produced from other field voltage sources generally indicated at 380. Such general voltage field sources 380 create electric fields E_{S} as best shown in FIG. 5. Electric field source 380 here represents numerous other voltage field sources which are typically found in automated handling systems, such as wafer production line 360. With this arrangement, sensor system 350 can be installed outside robotic process pathway 375 and provide real time monitoring of electrostatic charges on the semiconductor wafer 370. For example, monitoring system 350 is able to detect a 100 volt charged wafer 370 at a distance of 0.5 to 1 meter above pathway 375. Of course, once a relatively large electrostatic charge is sensed on semiconductor wafer 370, or for that matter reticles and carriers typically found in wafer production lines, corrected action can be taken to avoid unwanted electrostatic discharge.

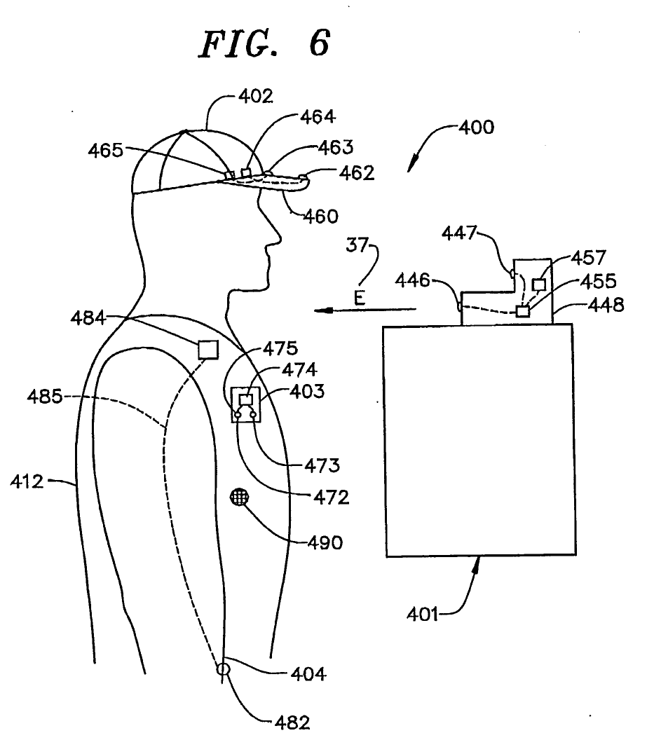

Various other forms of the invention are represented in FIG. 6. More specifically, there is shown an embodiment wherein a monitoring system 400 can be provided on sensitive equipment 401 or as a wearable arrangement. In particular, on one hand, system 400 can be incorporated into a hat 402, a badge 403 or on one or more sleeves 404 of protective clothing, such as a chemical suit, worn by a person 412. On the other hand, monitoring system 400 can be placed on equipment 401. At this point, it is important to note that these embodiments convey, in addition to variations in the articles that the sensor can be incorporated, that the electrostatic charge of interest could emanate from an object and be sensed with sensors on an individual, or emanate from the individual and be sensed with sensors on the object. In either case, the invention provides for sensing the charge at a considerable distance, as discussed further below, which enables corrective action to be taken.

In the embodiment where the individual carries the electrostatic charge, this is similar to the arrangement of FIG. 1, but with the monitoring system being carried by the object, rather than in a gateway or the like leading to the object. In the particular case shown, sensors 446 and 447 are mounted on a fixture 448 that keeps sensor 446 away from equipment 401, preferably at least 2 cm, keeps second sensor 447 away from first sensor 446, again preferably at least 2 cm, and further maintains second sensor away from equipment 401, preferably at least 4 cm. Sensors 446 and 447 are connected to a controller 455. If person 412 approaches equipment 401, a warning will be given if person 412 has accumulated a dangerously large static electric charge. A detection range of at least 2 to 3 meters is established with system 400 so that an advanced warning through a suitable unit 457 can be given, thereby allowing plenty of time to take corrective action. As indicated above, equipment 401 could take various forms such as, for example, an object in a clean room.

In other situations, a certain object 401 may produce an electric field E. As the body of a person 412 is a good conducting object, it can be subjected to and distort the local electric potential. In various situations, it would be desirable to sense the local electric potential at body 412. To this end, various arrangements are disclosed wherein monitoring system 400 is worn by person 412. In deploying a wearable sensor on person 412, the mounting position is important. In accordance with one embodiment shown, a baseball hat 402 provided with a visor 460 has be employed for the effective mounting of wearable capacitive sensors 462 and 463. Preferably, sensing electrodes 150, 250, referenced above, would preferably face outward in order to effectively sense the potential in free space. As shown in FIG. 6, sensors 462 and 463 located on visor 460, are mounted with one sensor 462 being closer to person 412 than the other sensor 462. Wiring (not separately labeled) is provided to transport sensed signals to a controller 464. A connection is also made to a conductive object, such as a fabric patch 465, on hat 402 near person 412 to provide a ground.

In another depicted form, system 400 may have sensors 472 and 473 located on badge 403. Once again, a controller 474 is provided with an electrical connection 475. Controller 474 is preferably incorporated into badge 403, but may also be located elsewhere. Finally, in another shown form of the invention, a sensor 482 is located on the sleeve(s) 404 of a garment, such as a chemical suit, worn by person 412. Once again, a controller 484 is provided with an electrical connection 485. Controllers 464, 474, 484 may each be connected to an alarm 490. Regardless of the particular form taken for these embodiments, the person carries the requisite monitoring system which will alert the person when they are subjected to an electrostatic potential above a predetermined level.

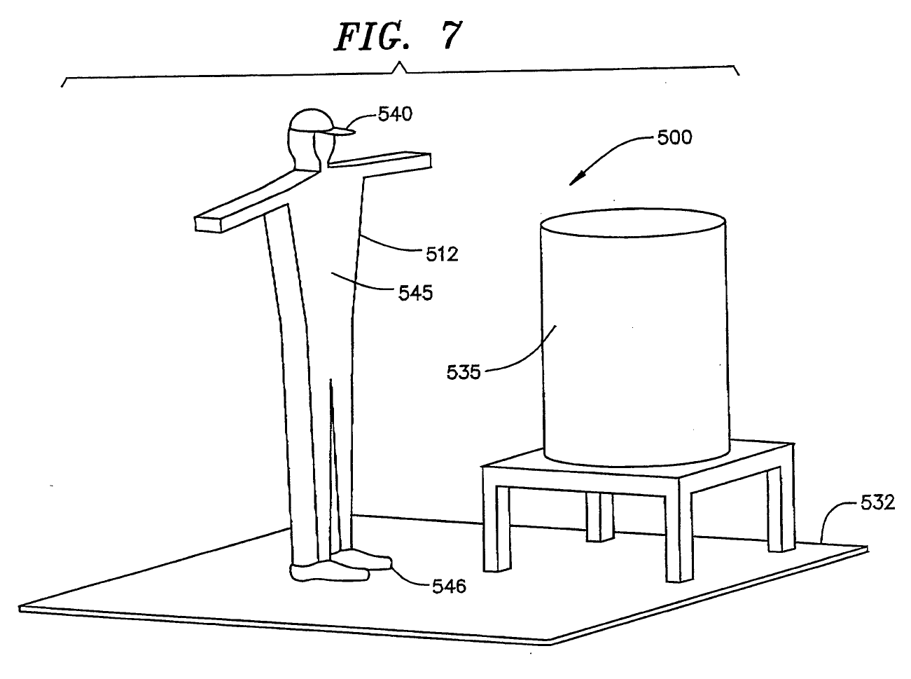

Turning now to FIG. 7, a human body model, used in the assistance of designing a wearable system, is shown at 500. As depicted, a person figure 512 is modeled on a grounding mat 532 at a certain distance from a high voltage source 535. In one tested arrangement, the potential distribution around high-voltage source 535 was modeled with an ElecNet electrostatic and electrodynamic modeling package. During a conducted simulation represented by FIG. 7, figure 512 was standing on and in electrical contact with grounding mat 532. Two sensor positions were simulated: one on a hat 540, 6 cm in front of figure 512 and 1.75 m above mat 532; and the other outside of a shirt 545, 1 cm in front of figure 512 and 1.10 m above mat 532. Voltage source 535 was modeled as a charge uniformly distributed on a metal can of 20 cm in diameter and 20 cm in height. The center of source 535 was positioned 1.1 m above mat 532.

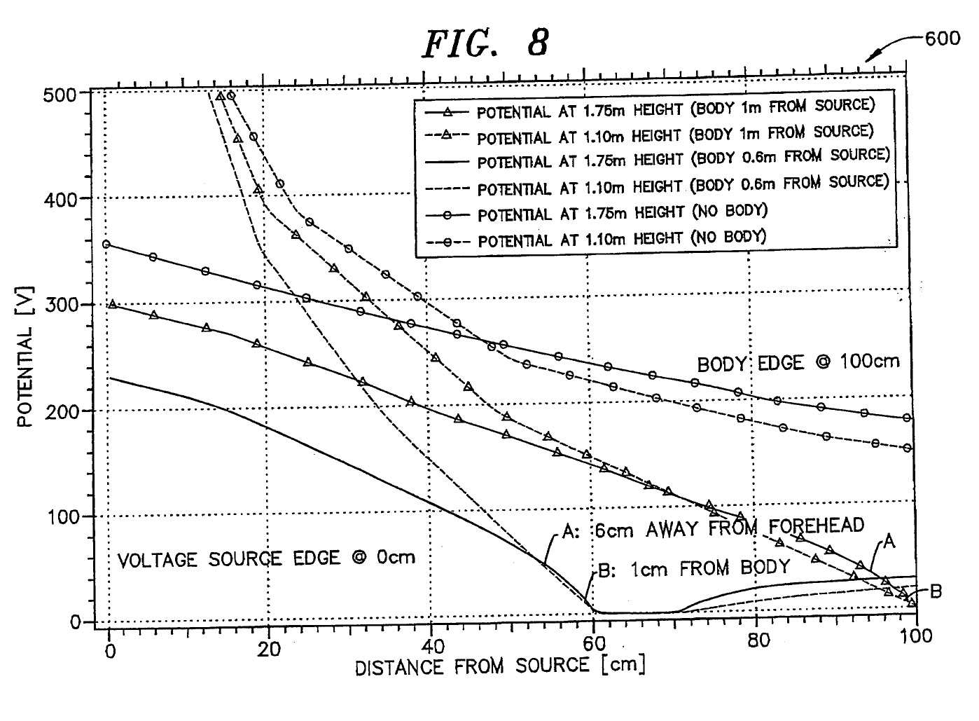

The simulation results are shown in FIG. 8 as a graph. Figure 512 is 60 cm and 100 cm from the edge of high-voltage source 535. The graph also shows simulated results without the effect of figure 512. Several points were noted. When a sensor is placed very close to figure 512, the potential is zero. The further away a sensor is from figure 512, the higher the potential. The potential is higher 6 cm in front of figure 512 on hat 540, than 1 cm in front of figure 512 on shirt 545. The potential is inversely proportional to the distance from source 535. Whether shoes 546 are conducting or insulating, the results are very similar, owing to capacitive coupling from figure 512 to mat 532. At a 1 m distance from a 1 kV source, the DC potential is 40 V near hat 540, and 4 V near shirt 545. With figure 512 walking at an average speed of 1 m/s, the signal has an effective frequency of at least 1 Hz, putting it well inside the measurement bandwidth of system 10.

Although described with reference to preferred embodiments of the invention, it should be readily understood that various changes and/or modifications could be made to the invention without departing from the spirit thereof. For example, the sensors could be mounted on many other objects, such as additional items worn by a person, for example, safety glasses or other types of clothing. In general, the invention is concerning with sensing a potentially hazardous electrostatic voltage charge potential, providing a suitable warning and enabling corrective measures to be taken at a significant distance from any location that damage can be inflicted by the potential. In any case, the invention is only intended to be limited by the scope of the following claims.

1. An electrostatic monitoring system for detecting a risk of electrostatic discharge by measuring a static electric field potential of an electric field produced by a source and providing an alert when the static electrical field potential exceeds a preset limit, said system comprising:
a capacitive sensor including an electrode exposed near to, but not in direct contact with, the source, and a preamplifier having an input electrically connected to said electrode by an electrical path and an output, said sensor being adapted to produce a sensed voltage signal based on the static electric field potential and said preamplifier producing an amplified voltage signal at the output based on the sensed voltage signal; and
a controller for receiving the amplified voltage signal and determining if the amplified voltage signal is above a predetermined threshold and, if the amplified voltage signal is above the threshold, then providing an alert on the risk of electrostatic discharge.

2. The system according to claim 1, further comprising: a ground electrode, wherein the sensor further includes a resistor located between the electrical path and the ground electrode.

3. The system according to claim 2, wherein the resistor has an input shunt resistance of about 1 Teraohm.

4. The system according to claim 1, wherein the sensor is mounted in an area containing a semiconductor wafer production line and the source is a semiconductor wafer.

5. The system according to claim 1, wherein the system is wearable on a human body.

6. The system according to claim 5, wherein the sensor is mounted on a hat such that, when the hat is worn, the sensor will be positioned away from the body.

7. The system according to claim 6, wherein the hat includes a visor, the sensor being mounted on the visor.

8. The system according to claim 1, further comprising: a ground electrode mounted on a brim of the hat, wherein the hat includes a conductive element, with the ground electrode making electrical contact with the body through the conductive element.

9. The system according to claim 5, wherein the sensor is mounted on a garment worn by an individual.

10. The system according to claim 9, wherein the sensor is provided on a badge.

11. The system according to claim 1, wherein the sensor further includes a capacitor located between the electrical path and a ground.

12. The system according to claim 11, wherein the capacitor adds a shunt capacitance of about 1 picofarad.

13. The system according to claim 1, wherein the sensor further comprises a feedback circuit including a feedback amplifier having an inverting input, a non-inverting input and an output, the output of the preamplifier being connected to the inverting input of the feedback amplifier and the output of the feedback amplifier being connected to the input of the preamplifier.

14. The system according to claim 13, further including a resistor in the feedback path, the resistor having a resistance value of at least about 10 Mega-ohms.

15. The system according to claim 13, wherein the sensor further includes an analog switch located between the inverting input and the output of the feedback amplifier.

16. The system according to claim 1, further comprising: a second sensor including a second electrode, located near, but not in direct contact with, the source, for producing a second sensed signal voltage based on the static electric field potential, a second preamplifier having an input electrically connected to said second electrode by a second electrical path and a second output, said second preamplifier producing a second amplified voltage signal at the second output based on the second sensed signal voltage, said controller receives the second amplified voltage signal and determines if the second amplified voltage signal is above the predetermined threshold.

17. The system according to claim 16, wherein the controller determines a direction to the source based on both the first amplified voltage signal and the second amplified voltage signal.

18. The system according to claim 16, wherein the first and second sensors are mounted on a doorway and the system is adapted to detect the electrostatic potential of people passing through the doorway.

19. The system according to claim 18, further comprising: an AC source, wherein the doorway causes a distortion of the static electric field potential, and the AC source is used to compensate for the distortion.

20. The system according to claim 16, wherein the first and second sensors are mounted to a machine, that is sensitive to static electrical discharge.

21. The system according to claim 20, wherein the first sensor is mounted at least 2 cm away from the machine, and the second sensor is mounted both at least 2 cm away from the first sensor and at least 4 cm away from the machine.

22. A method of detecting a risk of electrostatic discharge comprising:
measuring a static electric field potential of an electric field produced by a distant source;
producing a signal representative of the field potential; and
providing an alert when the electrical field potential exceeds a preset limit so that the electric field potential can be reduced in a harmless manner before an electrostatic discharge occurs.

23. The method of claim 22, further comprising: removing distortion from the measured signal.

24. The method of claim 22, wherein the static field potential is measured using a capacitive sensor provided on clothing.

25. The method of claim 24, further comprising: wearing the sensor on a hat.

26. The method of claim 22, wherein the static field potential is measured using a sensor mounted on a gasoline pump.

27. The method of claim 26, further comprising: mounting the sensor on a dispensing handle of the gasoline pump.

28. The method of claim 26, further comprising: shutting off the gasoline pump when the static electric field potential exceeds the preset limit.
